(19) United States
(12) Patent Application Publication
(10) Pub. No.: US 2020/0273856 A1
(43) Pub. Date: Aug. 27, 2020

(54) SEMICONDUCTOR INTEGRATED CIRCUIT INCLUDING A PROTECTION CIRCUIT AND SEMICONDUCTOR INTEGRATED CIRCUIT STRUCTURE

(71) Applicant: SK hynix Inc., Icheon-si Gyeonggi-do (KR)

(72) Inventors: Chang Hwi LEE, Seoul (KR); Jung Eon MOON, Yongin-si Gyeonggi-do (KR); Hyeng Ouk LEE, Yongin-si Gyeonggi-do (KR); Joung Cheul CHOI, Daejeon (KR)

(73) Assignee: SK hynix Inc., Icheon-si Gyeonggi-do (KR)

(21) Appl. No.: 16/674,345

(22) Filed: Nov. 5, 2019

(30) Foreign Application Priority Data
Feb. 26, 2019 (KR) 10-2019-0022313

(51) Int. Cl. H01L 27/02; H01L 27/092

(52) U.S. Cl. CPC H01L 27/0266; H01L 27/0262; H01L 27/092; H01L 27/0288; H01L 27/0255

(57) ABSTRACT

A semiconductor integrated circuit may include a first power line, a second power line, a third power line and a protection circuit. The first power line may receive an external voltage. The second power line may receive a voltage greater than the external voltage. The third power line may receive a voltage less than the external voltage applied to the first power line and the voltage applied to the second power line. The protection circuit may from a current path between the first power line, the second power line and the third power line when a surge voltage may be applied to the first power line to discharge the surge voltage to the third power line.

### CROSS-REFERENCE TO RELATED APPLICATION

The present application claims priority under 35 U.S.C. § 119(a) to Korean application number 10-2019-0022313, filed on Feb. 26, 2019, in the Korean Intellectual Property Office, which is incorporated herein by reference in its entirety.

### BACKGROUND

### 1. Technical Field

Various embodiments may generally relate to a semiconductor integrated circuit, and more particularly, to a semiconductor integrated circuit including a protection circuit, and a semiconductor integrated circuit structure.

### 2. Related Art

An electrical overstress (EOS) represented by a surge voltage may be a phenomenon whereby an abnormal transient voltage or a spark voltage flows into a voltage being applied to a power line of a semiconductor integrated circuit.

The EOS may cause failures within a circuit component, a circuit board, a triggering system, etc., and may cause these components to fail as well.

When the EOS is generated in an electronic circuit, a power voltage higher than an operational voltage applied to the power line may be applied within micro-seconds. Because the EOS may have influence on the internal circuit for a long time compared to an electrostatic discharge (EDS) influencing the internal circuit for pico-seconds, the internal circuit may be damaged greatly.

Therefore, it may be beneficial to remove the EOS, such as the surge voltage, by using a simple circuit.

### SUMMARY

In an embodiment of the present disclosure, a semiconductor integrated circuit may include a first power line, a second power line, a third power line and a protection circuit. The first power line may receive an external voltage. The second power line may receive a voltage greater than the external voltage. The third power line may receive a voltage less than the external voltage applied to the first power line and the voltage applied to the second power line. The protection circuit may form a pnpn parasitic current path between the first power line, the second power line and the third power line when a surge voltage is applied to the first power line to increase a voltage of the first power line higher greater than the voltage of the second power line by no less than a predetermined voltage.

In an embodiment of the present disclosure, a semiconductor integrated circuit structure may include a semiconductor substrate, a p-well, an n-well, a gate, a source and a drain of a PMOS transistor, a gate, a source and a drain of an NMOS transistor, a first power line, a second power line and a third power line. The p-well may be formed in the semiconductor substrate. The n-well may be formed in the p-well. The gate, the source and the drain of the PMOS transistor may be formed in the n-well. The gate, the source and the drain of the NMOS transistor may be formed in the p-well. The first power line may be electrically connected with the source of the PMOS transistor. The second power line may be electrically connected with the n-well. The third power line may be electrically connected with the source of the NMOS transistor. The first power line may receive an external voltage. The second power line may receive a voltage greater than the external voltage. The third power line may receive a voltage less than the external voltage applied to the first power line and the voltage applied to the second power line.

In an embodiment of the present disclosure, a semiconductor integrated circuit structure may include a semiconductor substrate, a p-well, a first n-well, a second n-well, a gate, a source and a drain of a PMOS transistor, a gate, a source and a drain of an NMOS transistor, a diode region, a first power line, a second power line and a third power line. The p-well may be formed in the semiconductor substrate. The first n-well may be formed in the p-well. The second n-well may be formed at a portion of the semiconductor substrate outside the first n-well. The gate, the source and the drain of the PMOS transistor may be formed in the first n-well. The gate, the source and the drain of the NMOS transistor may be formed in the p-well. The diode region may be formed in the second n-well. The first power line may be electrically connected with the diode region. The second power line may be electrically connected with the first n-well. The third power line may be electrically connected with the source of the NMOS transistor. The first power line may receive an external voltage. The second power line may receive a voltage greater than the external voltage. The third power line may receive a voltage less than the external voltage applied to the first power line and the voltage applied to the second power line. The second n-well may be electrically connected with the source of the PMOS transistor.

### BRIEF DESCRIPTION OF THE DRAWINGS

FIG. 1 is a block diagram illustrating a semiconductor integrated circuit in accordance with various embodiments;

FIG. 2 is a layout illustrating a first power line and a second power line in accordance with various embodiments;

FIG. 3 is a circuit diagram illustrating a protection circuit in accordance with various embodiments;

FIG. 4 is a cross-sectional view illustrating a protection circuit on a semiconductor substrate in accordance with various embodiments;

FIG. 5 is a view illustrating a parasitic path generated in a protection circuit when a surge voltage is generated in accordance with various embodiments;

FIG. 6 is a circuit diagram illustrating a protection circuit in accordance with various embodiments;

FIG. 7 is a cross-sectional view illustrating a protection circuit on a semiconductor substrate in accordance with various embodiments;

FIG. 8 is a view illustrating a parasitic path generated in a protection circuit when a surge voltage is generated in accordance with various embodiments;

FIG. 9 is a graph showing a current-voltage characteristic of protection circuits in accordance with various embodiments; and

FIG. 10 is a block diagram illustrating a semiconductor integrated circuit in accordance with various embodiments.

### DETAILED DESCRIPTION

Various embodiments will be described with reference to the accompanying drawings. The drawings are schematic illustrations of various embodiments (and intermediate structures). As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the spirit and scope of the description as defined in the appended claims.

The embodiments are described herein with reference to cross-section and/or plan illustrations. However, the embodiments should not be construed as limiting the concepts disclosed herein. Although a few embodiments will be shown and described, it will be appreciated by those of ordinary skill in the art that changes may be made in these embodiments without departing from the principles and spirit of the disclosure.

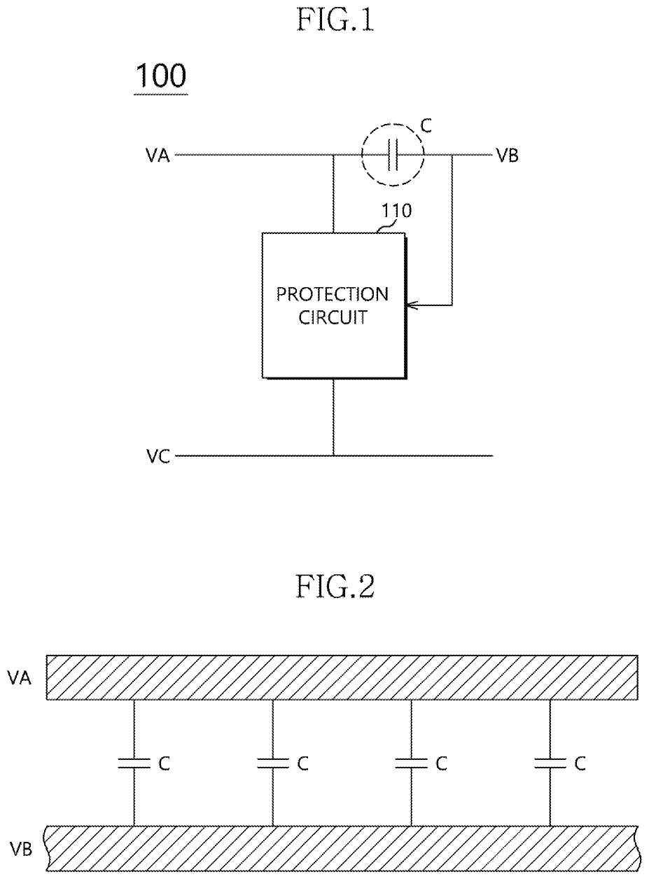

FIG. 1 is a block diagram illustrating a semiconductor integrated circuit in accordance with various embodiments.

Referring to FIG. 1, a semiconductor integrated circuit 100 may include a first power line VA, a second power line VB, a third power line VC, a protection circuit 110 and a capacitor C.

The first power line VA may receive an external voltage supplied from an external power supply. The first power line VA may be electrically coupled with a power pad.

The second power line VB may receive a voltage higher than the external voltage. For example, the voltage applied to the second power line VB may be formed by pumping the external voltage. In this case, the second power line VB may be electrically connected with an internal voltage generator. The second power line VB may receive the voltage from an additional power supply.

The third power line VC may receive a voltage lower than the external voltage applied to the first power line VA and the voltage applied to the second power line VB. For example, the voltage applied to the third power line VC may be a ground voltage VSS.

The protection circuit 110 may be turned-on when a sudden surge voltage is applied to the power pad. The protection circuit 110 may discharge the surge voltage into the third power line VC. In a normal operation mode, because the voltage of the first power line VA may be lower than the voltage of the second power line VB, the protection circuit 110 might not be turned-on. In contrast, when the voltage of the first power line VA may be temporarily higher than the voltage of the second power line VB due to the surge voltage, the protection circuit 110 may be turned-on in response to a voltage difference between the first power line VA and the second power line VB. The turning-on of the protection circuit 110 may result in generating a pnpn parasitic current path in the protection circuit 110. Thus, the protection circuit 110 may be driven only when the surge voltage may be included in the first power line VA to effectively discharge the surge voltage. In an embodiment, the protection circuit 110 may form a pnpn parasitic path between the first power line, the second power line and the third power line when a surge voltage is applied to the first power line. In an embodiment, the protection circuit 110 may form a pnpn parasitic path between the first power line, the second power line and the third power line when a surge voltage is applied to the first power line to increase a voltage of the first power line greater than the voltage of the second power line by no less than a predetermined voltage.

The capacitor C may correspond to a parasitic capacitor generated between the first power line VA and the second power line VB. In order to turn-on the protection circuit 110 only when the voltage of the first power line VA is higher than the voltage of the second power line VB by no less than a predetermined voltage, for example, a threshold voltage of a pn diode, it may be required to form the capacitor C between the first power line VA and the second power line VB. The word “predetermined” as used herein with respect to a parameter, such as a predetermined voltage, means that a value for the parameter is determined prior to the parameter being used in a process or algorithm. For some embodiments, the value for the parameter is determined before the process or algorithm begins. In other embodiments, the value for the parameter is determined during the process or algorithm but before the parameter is used in the process or algorithm.

FIG. 2 is a layout illustrating a first power line and a second power line in accordance with various embodiments.

Referring to FIG. 2, the first power line VA and the second power line VB may be arranged side-by-side to each other and spaced apart from each other by a gap to generate the capacitance C between the first power line VA and the second power line VB. In an embodiment, the second power line VB may be arranged substantially in parallel with the first power line VA and spaced apart from each other by a substantially uniform gap to form a capacitance C between the first power line VA and the second power line VB.

That is, when the voltage of the first power line VA is lower than the voltage of the second power line VB or the voltage difference between the first power line VA and the second power line VB is no more than the threshold voltage of the pn diode, it may be required to prevent the protection circuit 110 from being turned-on. Thus, the capacitance C for charging electric charges applied to the first power line VA is formed between the first power line VA and the second power line VB.

A capacitance C may be set in accordance with the threshold voltage of the pn diode. The capacitance C, as represented by the capacitors illustrated in FIG. 2, may be controlled by a distance between the first power line VA and the second power line VB, areas of the first and second power lines VA and VB, kinds of an insulating layer between the first power line VA and the second power line VB, etc. In some embodiments, a capacitor may be coupled between the first power line VA and the second power line VB to drive the protection circuit 110 only when a difference between the surge voltage applied to the first power line VA and the voltage of the second power line VB is no less than the predetermined voltage.

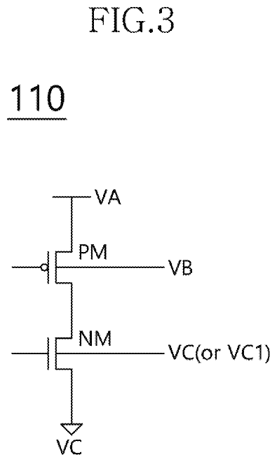

FIG. 3 is a circuit diagram illustrating a protection circuit in accordance with various embodiments.

Referring to FIG. 3, the protection circuit 110 may include an inverter connected between the first power line VA and the third power line VC. Particularly, the protection circuit 110 may include a PMOS transistor PM and an NMOS transistor NM.

The PMOS transistor PM may include a source connected to the first power line VA, and a drain connected to the NMOS transistor NM. A body of the PMOS transistor PM may be connected to the second power line VB. A gate of the PMOS transistor PM may be floated, connected to an output terminal of a previous circuit, or connected to a gate of the NMOS transistor NM.

The NMOS transistor NM may include a source connected to the third power line VC, and a drain connected to the PMOS transistor PM. In some embodiments, a body of the NMOS transistor NM may be connected to the third power line VC. In other embodiments, a body of the NMOS transistor NM may be electrically connected with a fourth power line VC1. A gate of the NMOS transistor NM may be floated, connected to the output terminal of the previous circuit, or the gate of the PMOS transistor PM.

The semiconductor integrated circuit may generally include an NMOS transistor and a PMOS transistor. Thus, the NMOS transistor NM and the PMOS transistor PM of the protection circuit 110 may be formed by processes substantially the same as those for forming the NMOS transistor and the PMOS transistor in other circuits. Further, spare transistors between the first power line VA and the third power line VC may be used for the NMOS transistor NM and the PMOS transistor PM of the protection circuit 110.

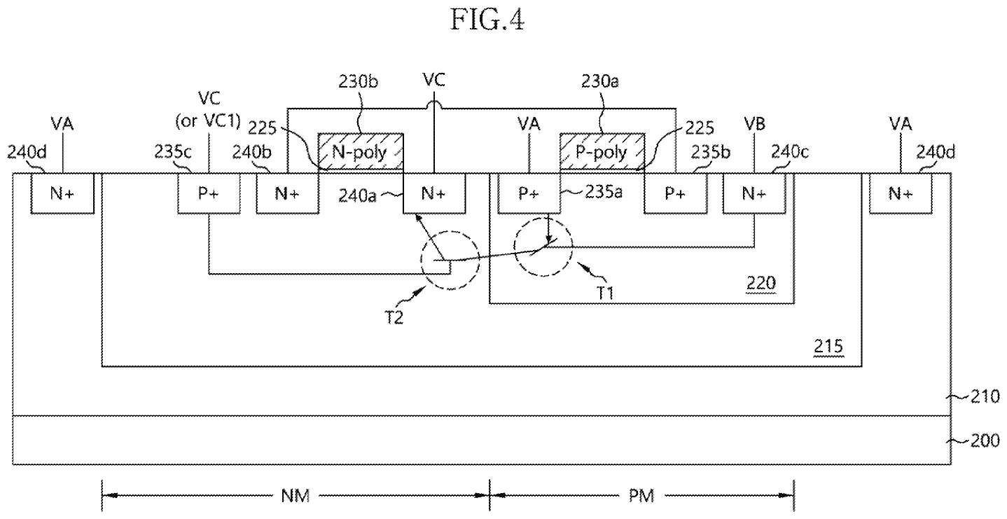

FIG. 4 is a cross-sectional view illustrating a protection circuit on a semiconductor substrate in accordance with various embodiments.

Referring to FIG. 4, a deep n-well 210 may be formed in a semiconductor substrate 200. In various embodiments, the semiconductor substrate 200 may include a p type silicon substrate. The deep n-well 210 may control substrate biases of the NMOS transistor NM and the PMOS transistor PM. A p-well 215 may be formed in the deep n-well 210. An n-well 220 may be formed in the p-well 215. The p-well 215 may have a depth substantially the same as a depth of the n-well 220. The depth of the p-well 215 and the n-well 220 may be shallower than a depth of the deep n-well 210. The n-well 220 may be an active region where the PMOS transistor PM in FIG. 3 may be formed. The p-well 215 arranged at a side of n-well 220 may be an active region where the NMOS transistor NM in FIG. 3 may be formed.

Gates 230a and 230b may be formed on the p-well 215 and the n-well 220. A gate insulating layer 225 may be formed between the gate 230a and the p-well 215, and between the gate 230b and the n-well 220.

P-type impurities having a high concentration may be implanted into the n-well 220 and the p-well 215 to define a gate 230a, a source 235a and a drain 235b of the PMOS transistor PM in the n-well 220 and a first body contact 235c for applying a voltage to the p-well 215. For example, the gate 230a of the PMOS transistor PM may include a polysilicon layer doped with p-type impurities (i.e., P-poly).

N-type impurities having a high concentration may be implanted into the n-well 220, the p-well 215 and an exposed portion of the deep n-well 210 to define a gate 230b, a source 240a and a drain 240b of the NMOS transistor NM in the p-well 215, a second body contact 240c for applying a voltage to the n-well 220, and a third body contact 240d for applying a voltage to the exposed portion of the deep n-well 210. For example, the gate 230b of the NMOS transistor NM may include a polysilicon layer doped with n-type impurities (i.e., N-poly).

The source 235a of the PMOS transistor PM may be electrically connected to the first power line VA. The drain 235b of the PMOS transistor PM may be electrically connected to the drain 240b of the NMOS transistor NM. The second body contact 240c of the n-well 220 may be electrically connected to the second power line VB. The third body contact 240d of the deep n-well 210 may be electrically connected to the first power line VA. The source 240a of the NMOS transistor NM may be electrically connected to the third power line VC. The drain 240b of the NMOS transistor NM may be electrically connected to the drain 235b of the PMOS transistor PM. The first body contact 235c making contact with the p-well 215 may make contact with the third power line VC, or may be electrically connected with a fourth power line VC1. The fourth power line VC1 may receive a voltage lower than the voltage of the third power line VC. FIG. 4 also illustrates n-type N+ and p-type P+ semiconductor materials.

FIG. 5 is a view illustrating a parasitic path generated in a protection circuit when a surge voltage is generated in accordance with various embodiments.

Referring to FIGS. 3 to 5, when the voltage of the first power line VA is lower than the voltage of the second power line VB in a normal mode, a reverse bias may be applied between the source 235a of the PMOS transistor PM and the n-well 220 so that a parasitic diode or a parasitic bipolar transistor might not be turned-on. Thus, the protection circuit 110 might not form any drive path between the first power line VA, the second power line VB and the third power line VC.

When the surge voltage is applied to the first power line VA to increase the voltage of the first power line VA greater than the voltage of the second power line VB by no less than a threshold voltage of a silicon diode, for example but not limited to, about 0.7V, a forward bias may be applied between the source 235a of the PMOS transistor PM, i.e., an emitter of a pnp bipolar transistor and the n-well 220, i.e., a base of the pnp bipolar transistor so that a parasitic pnp bipolar transistor T1 may be turned-on between the source 235a of the PMOS transistor PM, the n-well 220 and the p-well 215. Further, the reverse bias may be applied between the n-well 220, i.e., a collector of an npn bipolar transistor T2 and the p-well 215, i.e., a base of the npn bipolar transistor so that a parasitic npn bipolar transistor T2 may be turned-on between the n-well 220, the p-well 215 and the source 240a of the NMOS transistor NM.

Therefore, the surge voltage flowing into the first power line VA may be discharged into the third power line VC through a pnpn diode path or a thyristor path including the parasitic pnp bipolar transistor T1 and the parasitic npn bipolar transistor T2 generated between the first power line VA and the third power line VC.

In order to effectively turn-on the parasitic npn bipolar transistor T2, an applying voltage of the p-well 215 corresponding to the base of the parasitic npn bipolar transistor T2 may be changed. That is, according to various embodiments, the third power line VC may be electrically connected to the first body contact 235c for applying the voltage to the p-well 215. Alternatively, the fourth power line VC1 for transmitting the voltage lower than the voltage of the third power line VC may be connected to the first body contact 235c. The voltage of the fourth power line VC1 may be lower than the voltage of the third power line VC. Only when the p-well 215 is defined in the deep n-well 210 and the NMOS transistor NM of the protection circuit 110 is integrated in the p-well 215, the fourth power line VC1 may be connected to the first body contact 235c. When the p-well 215 is directly formed in the p type semiconductor substrate 200 or an NMOS transistor of another circuit is simultaneously integrated in the p-well 215, a voltage applied to the semiconductor substrate 200 or a body voltage of the NMOS transistor used for other applications may be changed.

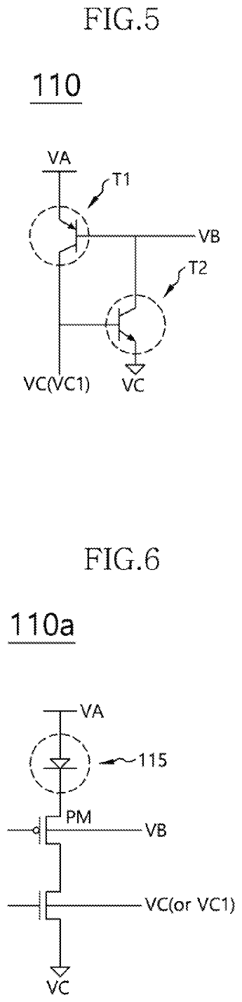

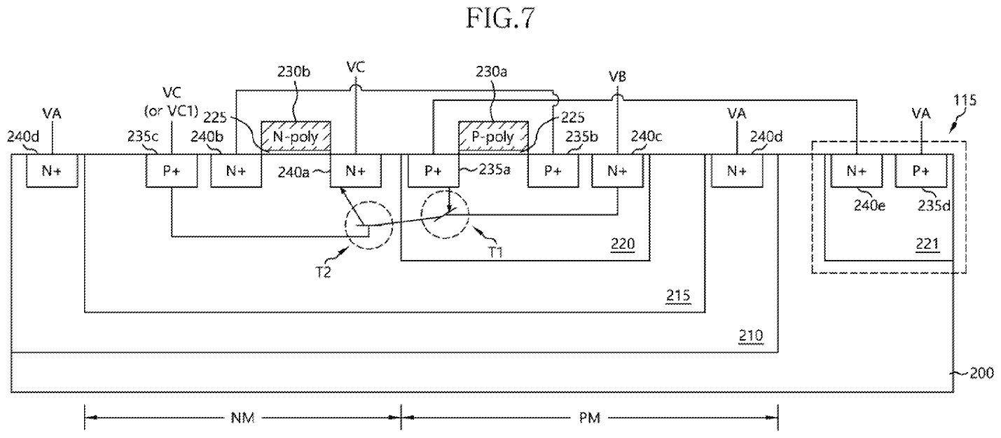

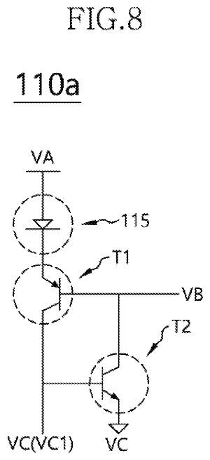

FIG. 6 is a circuit diagram illustrating a protection circuit in accordance with various embodiments, FIG. 7 is a cross-sectional view illustrating a protection circuit on a semiconductor substrate in accordance with various embodiments, and FIG. 8 is a view illustrating a parasitic path generated in a protection circuit when a surge voltage is generated in accordance with various embodiments.

A protection circuit 110a of these embodiments in FIGS. 6 to 8 may include elements substantially the same as those of the protection circuits 100 in FIGS. 2 to 4 except for further including a holding voltage control circuit 115.

Referring to FIG. 6, the holding voltage control circuit 115 may include a diode electrically connected between the first power line VA and the PMOS transistor PM. The diode of the holding voltage control circuit 115 may include an anode electrically connected to the first power line VA and a cathode electrically connected to the source of the PMOS transistor PM. Thus, the diode of the holding voltage control circuit 115 may increase the voltage applied to the drain of the PMOS transistor PM by the threshold voltage of the diode to increase a holding voltage of the protection circuit 110a.

The holding voltage control circuit 115 may include an n-well 221 formed in a portion of the semiconductor substrate 200 outside the deep n-well 210, a diode region 235d formed in the n-well 221, and a third body contact 240e for applying a voltage to the n-well 221.

The n-well 221 may be formed simultaneously with the n-well 220 corresponding to the active region of the PMOS transistor PM. For example, the n-well 221 may be directly formed in the semiconductor substrate 200.

The diode region 235d may include a p type impurity region having a high concentration for forming a pn junction with the n-well 221. The diode region 235d may be formed simultaneously with the source 235a and the drain 235b of the PMOS transistor PM and the first body contact 235c.

The third body contact 240e may be a region for applying a voltage to the n-well 221. The third body contact 240e may include an n type impurity region substantially the same as the type of the n-well 221. The third body contact 240e may be formed simultaneously with the source 240a and the drain 240b of the NMOS transistor NM, and the second and third body contacts 240c and 240d.

The diode region 235d may be connected to the first power line VA. The third body contact 240e may be electrically connected to the source 235a of the PMOS transistor PM.

Referring to FIGS. 7 and 8, when the surge voltage is included in the first power line VA, the voltage of the first power line VA may be applied to the diode region 235d. The diode of the holding voltage control circuit 115 may be generated between the diode region 235d and the n-well 221. When the holding voltage control circuit 115 is turned-on, an aggregate voltage of the surge voltage applied to the first power line VA added to the threshold voltage of the diode may be applied to the n-well 221. Further, the aggregate voltage applied to the n-well 221 may be transmitted to the source 235a of the PMOS transistor PM, i.e., the emitter of the pnp bipolar transistor T1. Therefore, the surge voltage and the holding voltage applied to the protection circuit 110a may be increased. As a result, a spontaneous latch-up may be prevented due to the increased holding voltage of the protection circuit 110a.

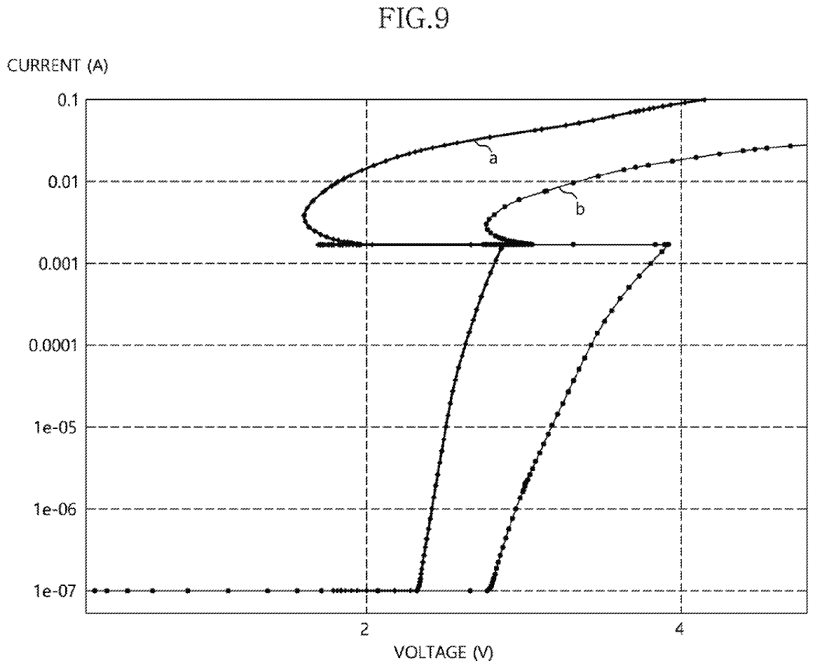

FIG. 9 is a graph showing a current-voltage characteristic of protection circuits 110 and 110a in accordance with various embodiments.

As shown in FIG. 9, when the protection circuit 110 does not include the holding voltage control circuit 115, the holding voltage (line a) may be about 1.7V at the surge voltage of no less than about 2.9V. In contrast, when the protection circuit 110a includes the holding voltage control circuit 115, the surge voltage may be increased to no less than about 3.8V by the diode of the holding voltage control circuit 115. Further, the holding voltage (line b) may also be increased to about 2.7V.

Therefore, the holding voltage control circuit 115 may be selectively inserted into the protection circuits 110 and 110a in accordance with the turn-on voltage and the holding voltage of the protection circuits 110 and 110a.

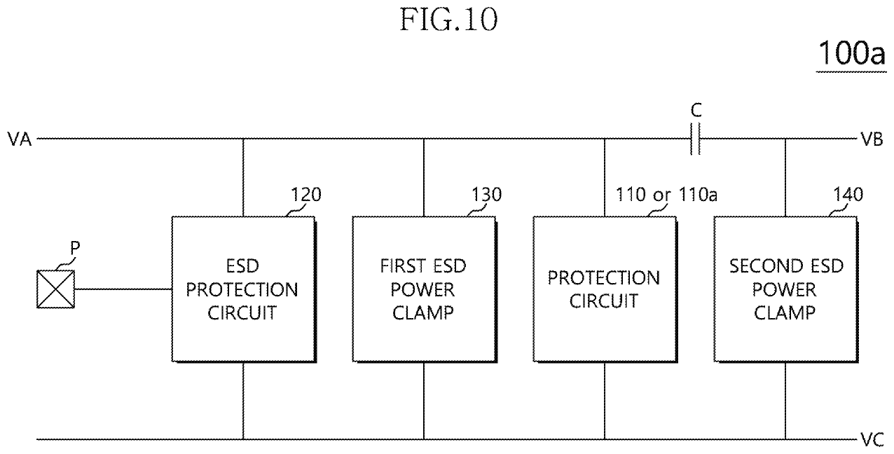

FIG. 10 is a block diagram illustrating a semiconductor integrated circuit in accordance with various embodiments.

Referring to FIG. 10, a semiconductor integrated circuit 100a may further include an electrostatic discharge (ESD) protection circuit 120, a first ESD power clamp 130 and a second ESD power clamp 140 as well as the protection circuit 110 or 110a.

The ESD protection circuit 120 may be connected with the first power line VA and the third power line VC to effectively discharge static electricity flowing from an input/output pad into the first power line VA or the third power line VC. An example of the ESD protection circuit 120 is disclosed in US 2018/0025934.

The first ESD power clamp 130 may be connected between the first power line VA and the third power line VC. The second ESD power clamp 140 may be connected between the second power line VB and the third power line VC. The first and second ESD power clamps 130 and 140 may include a reservoir capacitor for effectively discharging static electricity generated from the first power line VA and/or the second power line VB.

As mentioned above, when the static electricity flows through the I/P pad P and the power lines VA, VB, and VC, the ESD protection circuit 120 and the first and second ESD power clamps 130 and 140 may be driven without turning-on of the protection circuit 110 or 110a to discharge the static electricity.

When the surge voltage may be applied to the first power line VA to which the voltage lower than the voltage of the second power line VB may be applied, the protection circuit 110 or 110a may be turned-on in response to the voltage difference between the first power line VA and the second power line VB. Thus, the surge voltage to be applied to the first power line VA may be effectively discharged.

According to various embodiments, the protection circuit may generate the parasitic current path for discharging the surge voltage using the inverter connected between the power lines or using the inverter and holding voltage control circuit connected between the power lines. Thus, the surge voltage may be effectively removed using these structures.

Further, the protection circuits of various embodiments may include the inverter and/or the inverter with the holding voltage control circuit. Alternatively, the protection circuits may include the pnp bipolar transistor and the npn bipolar transistor integrated on the semiconductor substrate.

The above described embodiments are intended to illustrate and not to limit the present description. Various alternatives and equivalents are possible. The embodiments are not limited by the embodiments described herein. Nor are the embodiments limited to any specific type of semiconductor device.

What is claimed is:

1. A semiconductor integrated circuit comprising:
a first power line configured for receiving an external voltage;
a second power line for receiving a voltage greater than the external voltage;
a third power line configured for receiving a voltage less than the external voltage and the voltage applied to the second power line; and
a protection circuit configured for forming a pnpn parasitic current path between the first power line, the second power line and the third power line when a surge voltage is applied to the first power line to increase a voltage of the first power line higher greater than the voltage of the second power line by no less than a predetermined voltage.

2. The semiconductor integrated circuit of claim 1, wherein the protection circuit comprises:
a pnp bipolar transistor including a base connected to the second power line, an emitter connected to the first power line, and a collector connected to the third power line; and
an npn bipolar transistor including a base connected to the collector of the pnp bipolar transistor, an emitter connected to the third power line, and a collector connected to the second power line.

3. The semiconductor integrated circuit of claim 1, wherein the pnpn parasitic path is generated in the protection circuit when a difference between the surge voltage applied to the first power line and the voltage of the second power line is no less than a threshold voltage of a pn diode.

4. The semiconductor integrated circuit of claim 1, further comprising a holding voltage control circuit connected between the first power line and the protection circuit.

5. The semiconductor integrated circuit of claim 4, wherein the holding voltage control circuit comprises a pn diode including an anode connected to the first power line and a cathode connected to the protection circuit.

6. The semiconductor integrated circuit of claim 1, further comprising a capacitor between the first power line and the second power line to drive the protection circuit only when a difference between the surge voltage applied to the first power line and the voltage of the second power line is no less than the predetermined voltage,
wherein the predetermined voltage is a threshold voltage of a pn diode.

7. The semiconductor integrated circuit of claim 1, further comprising:
input/output pads;
an electrostatic discharge (ESD) protection circuit connected between the input/output pads, the first power line and the third power line to discharge static electricity flowing from the input/output pads;
a first ESD clamp connected between the first power line and the third power line to discharge static electricity flowing into the first power line; and
a second ESD clamp connected between the second power line and the third power line to discharge static electricity flowing into the second power line.

8. The semiconductor integrated circuit of claim 1, wherein the protection circuit comprises:
a PMOS transistor including a floated gate, and a source/drain connected to the first power line; and
an NMOS transistor including a floated gate, a source connected to the third power line, and a drain connected to the drain of the PMOS transistor,
wherein a body of the PMOS transistor is electrically connected with the second power line.

9. The semiconductor integrated circuit of claim 8, wherein a body of the NMOS transistor is electrically connected with the third power line.

10. The semiconductor integrated circuit of claim 8, wherein a voltage less than the voltage of the third power line is applied to a body of the NMOS transistor.

11. A semiconductor integrated circuit structure comprising:
a semiconductor substrate;
a p-well formed in the semiconductor substrate;
an n-well formed in the p-well;
a gate, a source, and a drain of a PMOS transistor formed in the n-well;
a gate, a source, and a drain of an NMOS transistor formed in the p-well;
a first power line electrically connected to the source of the PMOS transistor;
a second power line electrically connected to the n-well; and
a third power line electrically connected to the source of the NMOS transistor,
wherein the first power line receives an external voltage, the second power line receives a voltage greater than the external voltage, and the third power line receives a voltage less than the external voltage and the voltage applied to the second power line.

12. The semiconductor integrated circuit structure of claim 11, further comprising:
a first body contact formed in the p-well and electrically connected with the third power line; and
a second body contact formed in the n-well and electrically connected with the second power line.

13. The semiconductor integrated circuit structure of claim 11, further comprising:
a first body contact formed in the p-well to receive a voltage lower than the voltage applied to the third power line; and
a second body contact formed in the n-well and electrically connected with the second power line.

14. The semiconductor integrated circuit structure of claim 11, further comprising:
a deep n-well formed in the semiconductor substrate to surround the p-well; and
a third body contact formed in the deep n-well and electrically connected with the first power line.

15. The semiconductor integrated circuit structure of claim 11, wherein the first power line and the second power line are parallely extended to generate a capacitance between the first power line and the second power line.

16. A semiconductor integrated circuit structure comprising:
a semiconductor substrate;
a p-well formed in the semiconductor substrate;
a first n-well formed in the p-well;
a second n-well formed in a portion of the semiconductor substrate outside the p-well
a gate, a source, and a drain of a PMOS transistor formed in the first n-well;
a gate, a source, and a drain of an NMOS transistor formed in the p-well;
a diode region formed in the second n-well;
a first power line electrically connected to the diode region;
a second power line electrically connected to the n-well; and
a third power line electrically connected to the source of the is NMOS transistor,
wherein the first power line receives an external voltage, the second power line receives a voltage greater than the external voltage, and the third power line receives a voltage less than the external voltage and the voltage applied to the second power line, and
wherein the second n-well is electrically connected with the source of the PMOS transistor.

17. The semiconductor integrated circuit structure of claim 16, further comprising:
a first body contact formed in the p-well and electrically connected with the third power line; and
a second body contact formed in the first n-well and electrically connected with the second power line.

18. The semiconductor integrated circuit structure of claim 16, further comprising:
a first body contact formed in the p-well to receive a voltage less than the voltage applied to the third power line; and
a second body contact formed in the first n-well and electrically connected with the second power line.

19. The semiconductor integrated circuit structure of claim 16, further comprising:
a deep n-well formed in the semiconductor substrate to surround the p-well;
a third body contact formed in the deep n-well and electrically connected with the first power line; and
a fourth body contact formed in the second n-well,
wherein the fourth body contact is electrically connected with the source of the PMOS transistor.

20. The semiconductor integrated circuit structure of claim 16, wherein the first power line and the second power line are parallely extended to generate a capacitance between the first power line and the second power line.
